(19) United States
(12) Patent Application Publication
(10) Pub. No.: US 2024/0095431 A1
(43) Pub. Date: Mar. 21, 2024

(54) SIMULATION MODEL AUTHENTICATION

(71) Applicant: Taiwan Semiconductor Manufacturing Company, Ltd., Hsinchu (TW)

(72) Inventor: Katherine H. Chiang, New Taipei City (TW)

(21) Appl. No.: 18/171,384

(22) Filed: Feb. 20, 2023

Related U.S. Application Data
(60) Provisional application No. 63/376,287, filed on Sep. 20, 2022.

(51) Int. Cl. G06F 30/3308

(52) U.S. Cl. CPC G06F 30/3308

(57) ABSTRACT

A method of using a semiconductor device characterization description is disclosed. The method includes accessing the semiconductor device characterization description, accessing a first starter code, generating a first model authentication code (MAC) based on the semiconductor device characterization description and the first starter code, and transmitting the first starter code, the first MAC, and the semiconductor device characterization description to a model interface (MI).

### CROSS-REFERENCE TO RELATED APPLICATIONS

The application claims priority to U.S. Provisional Patent Application 63/376,287 filed Sep. 20, 2022, entitled “SIMULATION MODEL AUTHENTICATION,” the entire disclosure of which is incorporated herein by reference.

### TECHNICAL FIELD

The subject matter described herein relates to device models, and more particularly to authenticating simulation models.

### BACKGROUND

Semiconductor manufacturing processes include numerous fabrication steps or processes, each of which contributes to the formation of one or more semiconductor layers. Some layers are conductive and provide electrical connections between devices of an electronic system. Some layers may be formed, for example, by doping sections of a crystalline semiconductor substrate. In addition, one or more layers may be formed by adding, for example, conductive, resistive, and/or insulative layers on the crystalline semiconductor substrate. The layers collectively form semiconductor devices, which are simulated prior to manufacturing using simulation software which uses device models as descriptors for device performance.

Semiconductor arrangements are used in a multitude of electronic devices, such as mobile phones, laptops, desktops, tablets, watches, gaming systems, and various other industrial, commercial, and consumer electronics. Semiconductor arrangements generally comprise semiconductor portions and wiring portions formed inside the semiconductor portions.

### DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart diagram illustrating a method of generating and communicating a model authentication code according to some embodiments.

FIGS. 2-6 are flowchart diagrams illustrating methods of authenticating semiconductor device characterization descriptions according to some embodiments.

FIG. 7 is a swimming lane diagram illustrating a method of simulating a circuit according to some embodiments.

FIG. 8 is a schematic diagram illustrating a circuit simulation management system which manages and authenticates semiconductor device characterization descriptions, and simulates circuits according to some embodiments.

FIG. 9 illustrates a schematic diagram of a configuration for a computer system constructed in accordance with the present disclosure according to some embodiments.

When practical, similar reference numbers denote similar structures, features, or elements.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Several illustrative embodiments will now be described with respect to the accompanying drawings, which form a part hereof. The ensuing description provides embodiment(s) only and is not intended to limit the scope, applicability, or configuration of the disclosure. Rather, the ensuing description of the embodiment(s) will provide those skilled in the art with an enabling description for implementing one or more embodiments. It is understood that various changes may be made in the function and arrangement of elements without departing from the spirit and scope of this disclosure. In the following description, for the purposes of explanation, specific details are set forth in order to provide a thorough understanding of certain inventive embodiments. However, it will be apparent that various embodiments may be practiced without these specific details. The figures and description are not intended to be restrictive. The word “example” or “exemplary” is used herein to mean “serving as an example, instance, or illustration.” Any embodiment or design described herein as “exemplary” or “example” is not necessarily to be construed as preferred or advantageous over other embodiments or designs.

Because manufacturing semiconductor circuits is costly and generally involves significant lead time, an important part of the chip development process includes extensive software simulation of semiconductor circuits prior to manufacturing. The software which is used to simulate semiconductor circuits receives information representing a semiconductor circuit to be simulated, and the signals applied thereto, and calculates the electrical behavior of the semiconductor circuit based on descriptions of the individual devices of the semiconductor circuit. The descriptions of the individual devices include mathematical representations or models of the electrical behavior of each type of device for particular electrical inputs, and for particular environmental conditions, such as temperature. The mathematical representations or models are generalized for a particular device type, such as a transistor, and are parameterized, where the parameters represent particular expected characteristics of manufactured devices which affect electrical behavior of the manufactured semiconductor devices, such as physical and electrical properties of the manufactured semiconductor devices.

Semiconductor manufacturers manufacture semiconductor devices and extensively test and measure performance parameters of the manufactured semiconductor devices to determine values and distributions of values for each of the parameters for each of the types semiconductor devices and semiconductor structures for the mathematical representations of the device or structure behavior. Semiconductor manufacturers compile semiconductor device characterization descriptions which include parameters for the mathematical representations based on the determined values and determined distributions of values. In some embodiments, the semiconductor device characterization description may be or include a device model or a device model card for a simulator.

In addition, semiconductor manufacturers may additionally develop their own mathematical representations of the semiconductor devices and the semiconductor structures to improve simulation accuracy or correspondence with manufactured device performance. These mathematical representations may additionally be included in the semiconductor device characterization description.

In order for software simulations of the semiconductor devices to be sufficiently accurate, the semiconductor device characterization descriptions are expected to be correspondingly sufficiently accurate representations of the particular expected characteristics. Accordingly, it is important for software simulators to be using correct semiconductor device characterization descriptions.

For example, a semiconductor manufacture may update one or more semiconductor device characterization descriptions based on results of electrical tests and measured performance parameters of semiconductor devices more recently manufactured. Therefore, it is important that semiconductor simulations are performed using the updated semiconductor device characterization descriptions. Sometimes, a semiconductor manufacture may generate semiconductor device characterization descriptions which are provisional or are to be used only until a specified expiration date. Therefore, it is important that semiconductor simulations are performed using the provisional models only prior to their expiration date. Sometimes, a semiconductor chip designer may generate a custom semiconductor device characterization description, for example by changing one or more parameter values of a semiconductor device characterization description provided by a semiconductor manufacturer. Therefore, it is important that semiconductor simulations are performed using the expected semiconductor device characterization description, whether it be the custom semiconductor device characterization description, or that provided by the semiconductor manufacturer.

In the illustrated embodiments, systems and methods are described which provide secure authentication of semiconductor device characterization descriptions, for example, as part of a semiconductor circuit simulation exercise. The secure authentication of the semiconductor device characterization descriptions ensure that the proper semiconductor device characterization descriptions are used for simulating the semiconductor circuits.

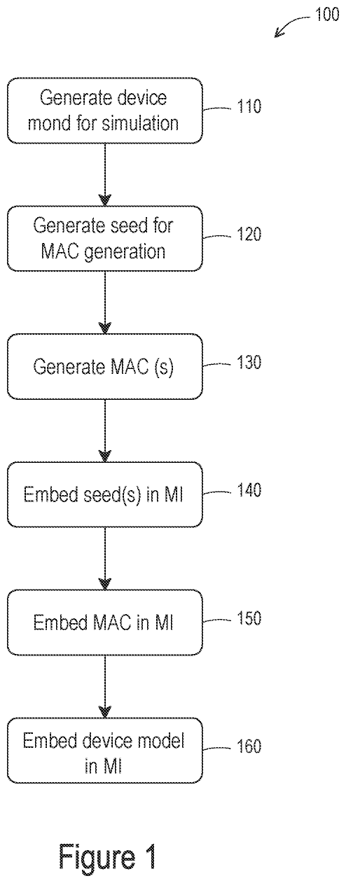

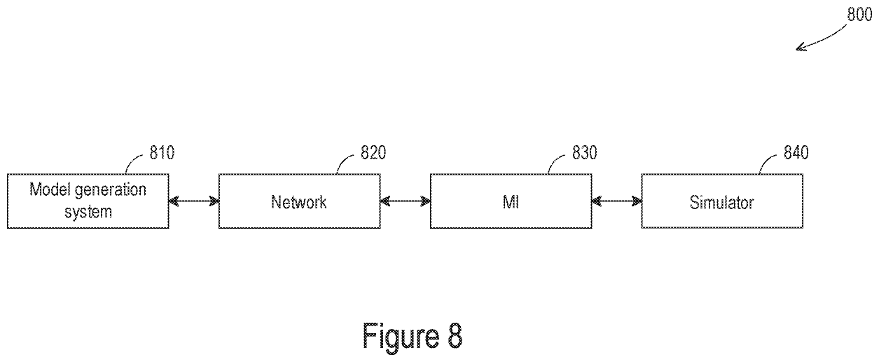

FIG. 1 is a flowchart diagram illustrating a method 100 of generating and communicating a model authentication code (MAC) according to some embodiments. The method 100 may be performed, for example, by a semiconductor manufacturer using, for example a model generation system, such as model generation system 810, discussed below with reference to FIG. 8.

At 110, the model generation system 810 generates a semiconductor device characterization description, for example, using procedures discussed above and/or otherwise known to those of skill in the art, where the semiconductor device characterization description includes characteristics and information discussed above, for example, discussed above and/or otherwise known to those of skill in the art. As a result of the activities of 110, a semiconductor device characterization description file may be generated. The semiconductor device characterization description file may, for example, be called a model card. In some embodiments, the semiconductor device characterization description file may include multiple model cards, and may, for example, be realized as multiple computer files.

At 120, the model generation system 810 generates one or more starter codes to be used at 130 to generate one or more MACs. The starter codes may be generated, for example, using a random number generator. In some embodiments, other methods are used to generate the one or more starter codes. In some embodiments, a length, or number of bits for the starter codes may correspond with the particular method of generating the one or more MACs at 130. In some embodiments, one or more invalidation starter codes may be generated, for example using a random number generator, or another method. In some embodiments, the one or more invalidation starter codes have a length, or number of bits identical to the starter codes generated for use in the MAC generation at 130. In some embodiments, the starter codes may be or include a seed and/or a seed code.

At 130, the one or more MACs are generated based on one or more starter codes generated at 120, as appropriate for the type of algorithm used to generate the one or more MACs, and additionally based on the semiconductor device characterization description. The MAC is generated based on the map generation algorithm using the one or more starter codes and based on the semiconductor device characterization description.

In some embodiments, the MAC generation algorithm includes a checksum algorithm. For example, the MAC generation algorithm may include one or more of: a BSD checksum algorithm, a SYS the checksum algorithm, a sum8 algorithm, and Internet checksum algorithm, a sum24 algorithm, a sum32 algorithm, a Fletcher-4 algorithm, a Fletcher-8 algorithm, and a Fletcher-16 algorithm, a Fletcher-32 algorithm, and Adler-32, an xor8 algorithm, a Luhn algorithm, a Verhoeff algorithm, and a Damm algorithm. In some embodiments, the MAC generation algorithm may include a checksum algorithm using one or more of: a sum algorithm, a sum with circular rotation algorithm, a once complement algorithm, a quasigroup operation algorithm, and another algorithm.

In some embodiments, the MAC generation algorithm includes a universal hash function algorithm. For example, the MAC generation algorithm may include one or more of: a Rabin fingerprint algorithm, a tabulation hashing algorithm, a universal one way hash function algorithm, and a Zobrist hashing algorithm. In some embodiments, the MAC generation algorithm may include a universal hash function algorithm using one or more of: a multiply algorithm, an XOR algorithm, and another algorithm.

In some embodiments, the MAC generation algorithm includes a non-cryptographic hash function algorithm. For example, the MAC generation algorithm may include one or more of: a Pearson hashing function. In some embodiments, the MAC generation algorithm may include a non-cryptographic hash function algorithm using one or more of: a Pearson hashing algorithm, Paul Hseih's SuperFastHash algorithm, a Buzhash algorithm, a Fowler-Noll-Vo algorithm, a Jenkins algorithm, a Bernstein algorithm, an Elf algorithm, a MurmurHash algorithm, a Fast-Hash algorithm, a SpookyHash algorithm, a CityHash algorithm, a FarmHash algorithm, a MetroHash algorithm, a numeric algorithm, an xxHash algorithm, a fast positive hash algorithm, a pHash algorithm, a dhash algorithm, a SDBM algorithm, and another algorithm.

In some embodiments, the MAC generation algorithm includes a keyed cryptographic hash function algorithm. For example, the MAC generation algorithm may include one or more of: a blake2 algorithm, a blake3 algorithm, an HMAC algorithm, a KMAC algorithm, an MD6 algorithm, a One-key MAC algorithm, a PMAC algorithm, a Polyl305-AES algorithm, a SipHash algorithm, a HighwayHash algorithm, a UMAC algorithm, a VMAC algorithm, and another algorithm.

In some embodiments, the MAC generation algorithm includes an unkeyed cryptographic hash function algorithm. For example, the MAC generation algorithm may include one or more of: a blake2s algorithm, a blake2b algorithm, a blake2x algorithm, a blake3 algorithm, a blake256 algorithm, a blake512 algorithm, an ECOH algorithm, an FSB algorithm, a GOST algorithm, a Grostl algorithm, an HAS-160 algorithm, a HAVAL algorithm, a JH algorithm, an LSH algorithm, an MD2 algorithm, an MD4 algorithm, an MD5 algorithm, an MD6 algorithm, a RadioGatun algorithm, a RIPEMD algorithm, a SHA algorithm, a Skein algorithm, a Snefru algorithm, a Spectral Hash algorithm, a Streebog algorithm, a SWIFFT algorithm, a Tiger algorithm, a Whirlpool algorithm, and another algorithm.

In some embodiments, the MAC is one of 4, 8, 16, 32, 64, 128, 256 bytes and another number of bytes. In some embodiments, the MAC has a variable length, for example depending upon at least one of the starter code and the semiconductor device characterization description.

At 140, the model generation system 810 interfaces with a model interface (MI), such as model interface 830, discussed below with reference to FIG. 8, for example, using a network such as communication network 820, discussed below with reference to FIG. 8. The model generation system 810 uses the network to communicate one or more starter codes generated at 120 to the model interface.

At 150, the model generation system 810 interfaces with the MI, for example, using the network to communicate one or more MACs generated at 130 to the model interface.

At 160, the model generation system 810 interfaces with the MI, for example, using the network to communicate the semiconductor device characterization description accessed at 110 to the model interface.

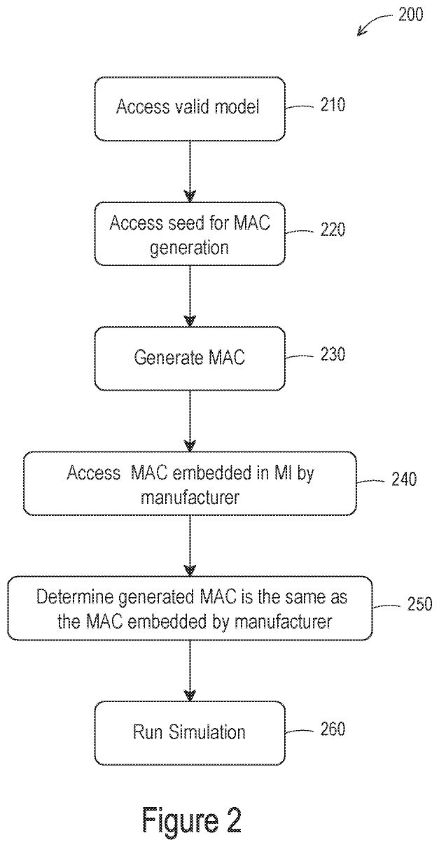

FIG. 2 is a flowchart diagram illustrating a method 200 of performing a simulation routine according to some embodiments. The method may be performed by a computer system running a simulation system comprising, for example, a simulator, such as simulator 840, discussed below with reference to FIG. 8, and having access to or running an MI, such as model interface 830, discussed below with reference to FIG. 8.

At 210, the MI accesses a valid semiconductor device characterization description.

In some embodiments, the MI accesses the valid semiconductor device characterization description in response to a signal from the simulator indicating that a simulation is to be performed on a circuit using the valid semiconductor device characterization description, where the signal includes a specific reference to the valid semiconductor device characterization description.

At 220, the MI accesses a starter code corresponding with the specific reference to the valid semiconductor device characterization description included in the signal from the simulator. In some embodiments, the starter code is accessible by the MI because the MI has received the starter code from a semiconductor manufacturer, for example in a process similar to that discussed above with reference to 140 of method 10, and has stored the received starter code in a memory. Accordingly, the starter code accessed at 220 may be identical to the starter code used to generate the MAC at 130 of method 100, discussed above with reference to FIG. 1.

At 230, the MI generates a MAC based on the starter code accessed at 220 and based on the valid semiconductor device characterization description accessed at 210 according to a MAC generation algorithm. In some embodiments, the MAC generation algorithm used at 230 is identical to the MAC generation algorithm used at 130 of method 100.

Because the MAC generation algorithm used at 230 is identical to the MAC generation algorithm used at 130 of method 100, and because the starter code accessed at 220 is identical to the starter code used to generate the MAC at 130 of method 100, if the semiconductor device characterization description used to generate the MAC at 230 is identical to the semiconductor device characterization description used to generate the MAC at 130 of method 100, the MAC generated at 230 is identical to the MAC generated at 130 of method 100. In contrast, if the semiconductor device characterization description used to generate the MAC at 230 is not identical to the semiconductor device characterization description used to generate the MAC at 130 of method 100, the MAC generated at 230 is different from the MAC generated at 130 of method 100.

In this case, because the semiconductor device characterization description used to generate the MAC at 230 is valid, it is identical to the semiconductor device characterization description used to generate the MAC at 130 of method 100. Accordingly, the MAC generated at 230 is identical to the MAC generated at 130 of method 100.

At 240, the MI accesses a MAC corresponding with a valid model corresponding with the specific reference to the semiconductor device characterization description included in the signal from the simulator. In some embodiments, the accessed MAC is accessible by the MI because the MI has received the MAC from a semiconductor manufacturer, for example in a process similar to that discussed above with reference to 150 of method 100, and has stored the received MAC in a memory. Accordingly, if the semiconductor device characterization description used to generate the MAC at 230 is identical to the semiconductor device characterization description used to generate the MAC at 130 of method 100, the MAC accessed at 240 is identical to the MAC generated at 230. In contrast, if the semiconductor device characterization description used to generate the MAC at 230 is not identical to the semiconductor device characterization description used to generate the MAC at 130 of method 100, the accessed MAC is different from the MAC generated at 230.

At 250, the accessed MAC is compared with the MAC generated at 230. In this case, because the model accessed at 210 is valid, the accessed MAC is determined to be identical to the MAC generated at 230.

As a consequence of the accessed MAC being identical to the MAC generated at 230, at 260, the simulator simulates the circuit using the valid model accessed at 210, using simulation processes and techniques known to those of skill in the art. Once the simulation completes, a result of the simulation is generated, and stored for example, as a file. Because the accessed MAC and the generated MAC are compared before simulation, secure authentication of the semiconductor device characterization descriptions ensure that the proper semiconductor device characterization descriptions are used for simulating the semiconductor circuits.

In some embodiments, as a consequence of the accessed MAC being identical to the MAC generated at 230, instead of simulating the circuit at 260, the computer system repeats steps 220, 230, 240, and 250, where 220 is repeated using a second seed, where 230 is repeated using a second MAC generation algorithm, 240 is repeated using a second valid MAC, and 250 is repeated with a second MAC generated at the repeated instance of 230 and with the second valid MAC accessed at 240. In addition, as a consequence of the second accessed MAC being identical to the second MAC generated at 230, at 260, the simulator simulates the circuit using the valid model accessed at 210, using simulation processes and techniques known to those of skill in the art. In some embodiments, the MAC generation algorithm used in the first iteration of 230 is faster and/or less complicated than the MAC generation algorithm used in the second iteration of 230.

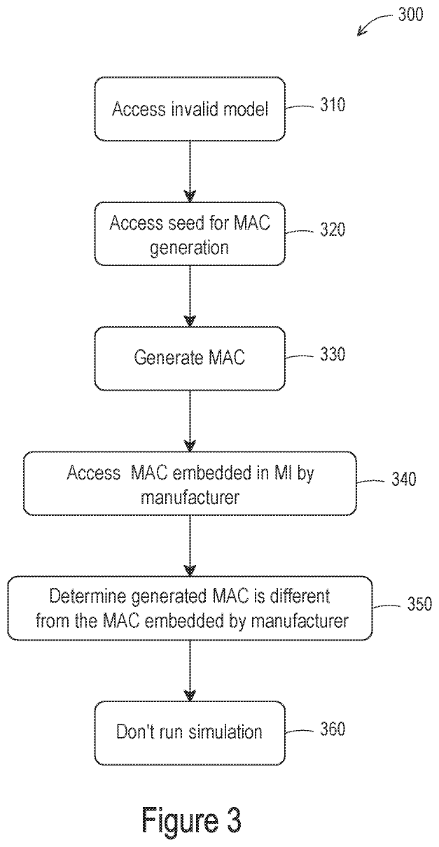

FIG. 3 is a flowchart diagram illustrating a method 300 of performing a simulation routine according to some embodiments. The method may be performed by a computer system running a simulation system comprising, for example, a simulator, such as simulator 840, discussed below with reference to FIG. 8, and having access to or running an MI, such as model interface 830, discussed below with reference to FIG. 8.

At 310, the MI accesses an invalid semiconductor device characterization description. The semiconductor device characterization description may be invalid, for example, because the semiconductor device characterization description has been modified by a user. In some embodiments, the semiconductor device characterization description may be invalid, for example, because the semiconductor device characterization description has an expiration date which has passed.

In some embodiments, the MI accesses the invalid semiconductor device characterization description in response to a signal from the simulator indicating that a simulation is to be performed on a circuit using the invalid semiconductor device characterization description, where the signal includes a specific reference to the invalid semiconductor device characterization description.

At 320, the MI accesses a starter code corresponding with the specific reference to the invalid semiconductor device characterization description included in the signal from the simulator. In some embodiments, the starter code is accessible by the MI because the MI has received the starter code from a semiconductor manufacturer, for example in a process similar to that discussed above with reference to 140 of method 10, and has stored the received starter code in a memory. Accordingly, the starter code accessed at 320 may be identical to the starter code used to generate the MAC at 130 of method 100, discussed above with reference to FIG. 1.

At 330, the MI generates a MAC based on the starter code accessed at 320 and based on the invalid semiconductor device characterization description accessed at 310 according to a MAC generation algorithm. In some embodiments, the MAC generation algorithm used at 330 is identical to the MAC generation algorithm used at 130 of method 100.

Because the MAC generation algorithm used at 330 is identical to the MAC generation algorithm used at 130 of method 100, and because the starter code accessed at 320 is identical to the starter code used to generate the MAC at 130 of method 100, if the semiconductor device characterization description used to generate the MAC at 330 is identical to the semiconductor device characterization description used to generate the MAC at 130 of method 100, the MAC generated at 330 is identical to the MAC generated at 130 of method 100. In contrast, if the semiconductor device characterization description used to generate the MAC at 330 is not identical to the semiconductor device characterization description used to generate the MAC at 130 of method 100, the MAC generated at 330 is different from the MAC generated at 130 of method 100.

In this case, because the semiconductor device characterization description used to generate the MAC at 330 is invalid, it is different from the semiconductor device characterization description used to generate the MAC at 130 of method 100. Accordingly, the MAC generated at 330 is different from the MAC generated at 130 of method 100.

At 340, the MI accesses a MAC corresponding with a valid model corresponding with the specific reference to the semiconductor device characterization description included in the signal from the simulator. In some embodiments, the accessed MAC is accessible by the MI because the MI has received the MAC from a semiconductor manufacturer, for example in a process similar to that discussed above with reference to 150 of method 100, and has stored the received MAC in a memory. Accordingly, if the semiconductor device characterization description used to generate the MAC at 330 is identical to the semiconductor device characterization description used to generate the MAC at 130 of method 100, the MAC accessed at 340 is identical to the MAC generated at 330. In contrast, if the semiconductor device characterization description used to generate the MAC at 330 is not identical to the semiconductor device characterization description used to generate the MAC at 130 of method 100, the accessed MAC is different from the MAC generated at 330.

At 350, the accessed MAC is compared with the MAC generated at 330. In this case, because the model accessed at 310 is invalid, the accessed MAC is determined to be different from the MAC generated at 330.

As a consequence of the accessed MAC being different from the MAC generated at 330, at 360, the simulator does not simulate the circuit using the invalid model accessed at 310. Because the accessed MAC and the generated MAC are compared before simulation, secure authentication of the semiconductor device characterization descriptions ensure that the improper semiconductor device characterization descriptions are not used for simulating the semiconductor circuits.

In some embodiments, in response to determining that the accessed MAC is different from the MAC generated at 330, at 360, the simulator causes an error message to be displayed for a user, where the error message indicates that the semiconductor device characterization description accessed at 310 is not valid. In some embodiments, the message includes a prompt for an input indicating whether the invalid model should be used despite it being different from the model received from the semiconductor manufacturer. In some embodiments, in response to receiving an indication that the invalid model should be used despite it being different from the model received from the semiconductor manufacturer, the simulator simulates the circuit using the invalid model accessed at 310, using simulation processes and techniques known to those of skill in the art. In some embodiments, the message includes a prompt for a new semiconductor device characterization description to be referenced. In some embodiments, if a new semiconductor device characterization description is referenced, the method 300 returns to 310 using the new semiconductor device characterization description.

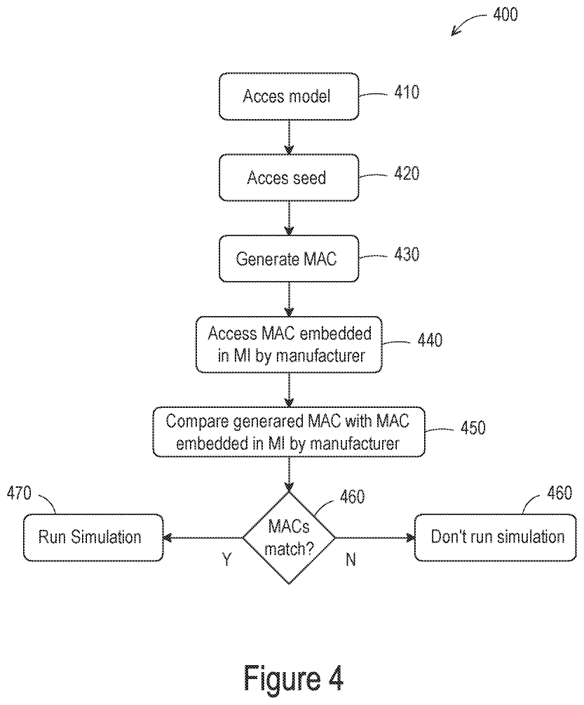

FIG. 4 is a flowchart diagram illustrating a method 400 of performing a simulation routine according to some embodiments. The method may be performed by a computer system running a simulation system comprising, for example, a simulator, such as simulator 840, discussed below with reference to FIG. 8, and having access to or running an MI, such as model interface 830, discussed below with reference to FIG. 8.

At 410, the MI accesses a semiconductor device characterization description. The semiconductor device characterization description may be valid or invalid.

In some embodiments, the MI accesses the semiconductor device characterization description in response to a signal from the simulator indicating that a simulation is to be performed on a circuit using the semiconductor device characterization description, where the signal includes a specific reference to the semiconductor device characterization description.

At 420, the MI accesses a starter code corresponding with the specific reference to the semiconductor device characterization description included in the signal from the simulator. In some embodiments, the starter code is accessible by the MI because the MI has received the starter code from a semiconductor manufacturer, for example, in a process similar to that discussed above with reference to 140 of method 10, and has stored the received starter code in a memory. Accordingly, the starter code accessed at 420 may be identical to the starter code used to generate the MAC at 130 of method 100, discussed above with reference to FIG. 1.

At 430, the MI generates a MAC based on the starter code accessed at 420 and based on the semiconductor device characterization description accessed at 410 according to a MAC generation algorithm, for example, identical to the MAC generation algorithm used at 130 of method 100.

At 440, the MI accesses a MAC corresponding with a valid model corresponding with the specific reference to the semiconductor device characterization description included in the signal from the simulator. In some embodiments, the accessed MAC is accessible by the MI because the MI has received the MAC from a semiconductor manufacturer, for example in a process similar to that discussed above with reference to 150 of method 100, and has stored the received MAC in a memory.

Accordingly, if the semiconductor device characterization description and the starter code used to generate the MAC at 430 are identical to the semiconductor device characterization description and starter code used to generate the MAC at 130 of method 100, the MAC accessed at 440 is identical to the MAC generated at 430. In contrast, if the semiconductor device characterization description or starter code used to generate the MAC at 430 are not identical to the semiconductor device characterization description or starter code used to generate the MAC at 130 of method 100, the accessed MAC is different from the MAC generated at 430.

At 450, the MAC accessed at 440 is compared with the MAC generated at 430.

If the MAC accessed at 440 is determined to be identical to the MAC generated at 430, at 460, the method continues to 470, where the simulator simulates the semiconductor circuit using the model accessed at 410, according to simulation processes and techniques known to those of skill in the art. Once the simulation completes, a result of the simulation is generated, and stored for example, as a file. Because the accessed MAC and the generated MAC are compared before simulation, secure authentication of the semiconductor device characterization descriptions ensure that the proper semiconductor device characterization descriptions are used for simulating the semiconductor circuits.

If the MAC accessed at 440 is determined to be different from the MAC generated at 430, at 460, the method continues to 480, discussed below.

In some embodiments, as a consequence of the MAC accessed at 440 being identical to the MAC generated at 430, instead of simulating the circuit at 470, the computer system repeats steps 420, 430, 440, 450, and 460, where 420 is repeated using a second seed, where 430 is repeated using a second MAC generation algorithm, where 440 is repeated using a second MAC from the semiconductor manufacturer, where 450 is repeated with the second MAC generated at the repeated instance of 430 and with the second MAC accessed at 440. In some embodiments, the MAC generation algorithm used in the first iteration of 430 is faster and/or less complicated than the MAC generation algorithm used in the second iteration of 430.

If the second accessed MAC is determined to be identical to the second MAC generated at 430, at 460, the method continues to 470, where the simulator simulates the semiconductor circuit using the model accessed at 410, according to simulation processes and techniques known to those of skill in the art. Once the simulation completes, a result of the simulation is generated, and stored for example, as a file.

If the second accessed MAC is determined to be different from the second MAC generated at 430, at 460 the method continues to 480.

At 480, the circuit is not simulated. In some embodiments, at 480, the simulator causes an error message to be displayed for a user, where the error message indicates that the semiconductor device characterization description accessed at 410 is not valid. In some embodiments, the message includes a prompt for an input indicating whether the invalid model should be used despite it being different from the model received from the semiconductor manufacturer. In some embodiments, in response to receiving an indication that the semiconductor device characterization description should be used despite it being different from the model received from the semiconductor manufacturer, the simulator simulates the circuit using the semiconductor device characterization description accessed at 410, according to simulation processes and techniques known to those of skill in the art. In some embodiments, the message includes a prompt for a new semiconductor device characterization description to be referenced. In some embodiments, if a new semiconductor device characterization description is referenced, the method 400 returns to 410 using the new semiconductor device characterization description. Because the accessed MAC and the generated MAC are compared before simulation, secure authentication of the semiconductor device characterization descriptions ensure that the improper semiconductor device characterization descriptions are not used for simulating the semiconductor circuits.

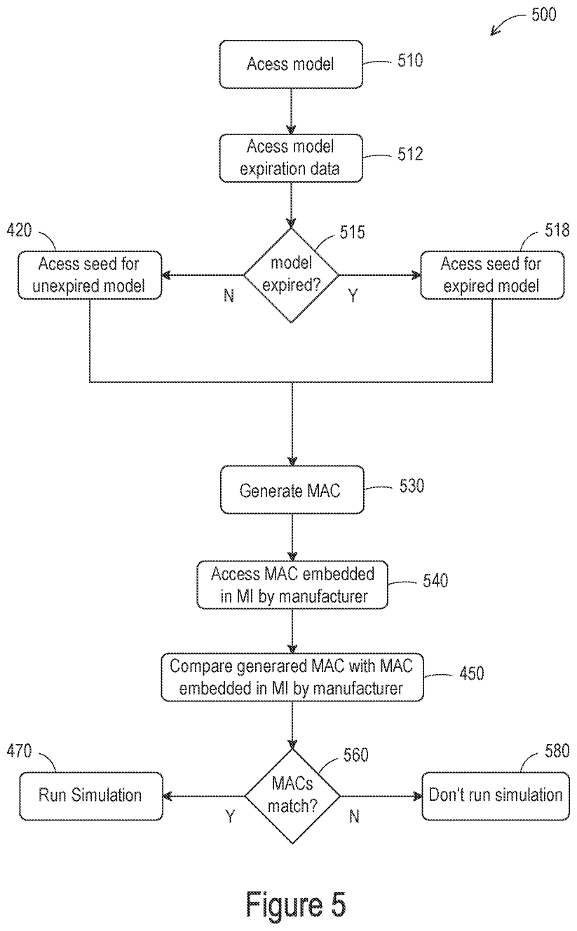

FIG. 5 is a flowchart diagram illustrating a method 500 of performing a simulation routine according to some embodiments. The method may be performed by a computer system running a simulation system comprising, for example, a simulator, such as simulator 840, discussed below with reference to FIG. 8, and having access to or running an MI, such as model interface 830, discussed below with reference to FIG. 8.

At 510, the MI accesses a semiconductor device characterization description. The semiconductor device characterization description may be valid or invalid. In some embodiments, the MI accesses the semiconductor device characterization description in response to a signal from the simulator indicating that a simulation is to be performed on a circuit using the semiconductor device characterization description, where the signal includes a specific reference to the semiconductor device characterization description.

At 512, the MI accesses an expiration date for the device mode accessed at 510.

At 515, the MI compares the expiration date accessed at 512, and compares the accessed expiration date with a comparison date, such as the current date. Based on the comparison, the MI determines whether the semiconductor device characterization description accessed at 510 has expired. For example, if the comparison date is more recent than the expiration date accessed at 512, the MI determines that the semiconductor device characterization description accessed at 510 has expired, and the method proceeds to 518, discussed below. If the comparison date is not more recent than the expiration date accessed at 512, the MI determines that the semiconductor device characterization description accessed at 510 has not expired, and the method proceeds to 520, discussed below.

At 518, the MI accesses a starter code corresponding with an expired semiconductor device characterization description. In some embodiments, the starter code is accessible by the MI because the MI has received the accessed starter code from a semiconductor manufacturer, for example, in a process similar to that discussed above with reference to 140 of method 10, and has stored the received starter code in a memory.

At 520, the MI accesses a starter code corresponding with the specific reference to the semiconductor device characterization description included in the signal from the simulator. In some embodiments, the starter code is accessible by the MI because the MI has received the starter code from a semiconductor manufacturer, for example, in a process similar to that discussed above with reference to 140 of method 10, and has stored the received starter code in a memory. Accordingly, the starter code accessed at 520 may be identical to the starter code used to generate the MAC at 130 of method 100, discussed above with reference to FIG. 1.

At 530, the MI generates a MAC based on the starter code accessed at either of 518 and 520 and based on the semiconductor device characterization description accessed at 510 according to a MAC generation algorithm, for example, identical to the MAC generation algorithm used at 130 of method 100.

At 540, the MI accesses a MAC corresponding with a valid model corresponding with the specific reference to the semiconductor device characterization description included in the signal from the simulator. In some embodiments, the accessed MAC is accessible by the MI because the MI has received the MAC from a semiconductor manufacturer, for example in a process similar to that discussed above with reference to 150 of method 100, and has stored the received MAC in a memory.

Accordingly, if the semiconductor device characterization description and the starter code used to generate the MAC at 530 are identical to the semiconductor device characterization description and starter code used to generate the MAC at 130 of method 100, the MAC accessed at 540 is identical to the MAC generated at 530. In contrast, if the semiconductor device characterization description or starter code used to generate the MAC at 530 are not identical to the semiconductor device characterization description or starter code used to generate the MAC at 130 of method 100, the accessed MAC is different from the MAC generated at 530.

At 550, the MAC accessed at 540 is compared with the MAC generated at 530.

If the MAC accessed at 540 is determined to be identical to the MAC generated at 530, at 560, the method continues to 570, where the simulator simulates the semiconductor circuit using the model accessed at 510, according to simulation processes and techniques known to those of skill in the art. Once the simulation completes, a result of the simulation is generated, and stored for example, as a file.

If the MAC accessed at 540 is determined to be different from the MAC generated at 530, at 560, the method continues to 580, discussed below. In some embodiments, the MAC accessed at 540 is different from the MAC generated at 530 because the semiconductor device characterization description accessed at 510 is different from the semiconductor device characterization description used to generate the MAC accessed at 540. In some embodiments, the MAC accessed at 540 is different from the MAC generated at 530 because the starter code accessed at 518 is different from the starter code used to generate the MAC accessed at 540.

In some embodiments, as a consequence of the MAC accessed at 540 being identical to the MAC generated at 530, instead of simulating the circuit at 570, the computer system repeats steps 520, 530, 540, 550, and 560, where 520 is repeated using a second seed, where 530 is repeated using a second MAC generation algorithm, where 540 is repeated using a second MAC from the semiconductor manufacturer, where 550 is repeated with the second MAC generated at the repeated instance of 530 and with the second MAC accessed at 540. In some embodiments, the MAC generation algorithm used in the first iteration of 530 is faster and/or less complicated than the MAC generation algorithm used in the second iteration of 530.

If the second accessed MAC is determined to be identical to the second MAC generated at 530, at 560, the method continues to 570, where the simulator simulates the semiconductor circuit using the model accessed at 510, according to simulation processes and techniques known to those of skill in the art. Once the simulation completes, a result of the simulation is generated, and stored for example, as a file. Because the accessed MAC and the generated MAC are compared before simulation, secure authentication of the semiconductor device characterization descriptions ensure that the proper semiconductor device characterization descriptions are used for simulating the semiconductor circuits.

If the second accessed MAC is determined to be different from the second MAC generated at 530, at 560 the method continues to 580.

At 580, the circuit is not simulated. In some embodiments, at 580, the simulator causes an error message to be displayed for a user, where the error message indicates that the semiconductor device characterization description accessed at 510 is not valid. In some embodiments, the message includes a prompt for an input indicating whether the invalid model should be used despite it being different from the model received from the semiconductor manufacturer. In some embodiments, in response to receiving an indication that the semiconductor device characterization description should be used despite it being different from the model received from the semiconductor manufacturer, the simulator simulates the circuit using the semiconductor device characterization description accessed at 510, according to simulation processes and techniques known to those of skill in the art. In some embodiments, the message includes a prompt for a new semiconductor device characterization description to be referenced. In some embodiments, if a new semiconductor device characterization description is referenced, the method 500 returns to 510 using the new semiconductor device characterization description. Because the accessed MAC and the generated MAC are compared before simulation, secure authentication of the semiconductor device characterization descriptions ensure that the improper semiconductor device characterization descriptions are not used for simulating the semiconductor circuits.

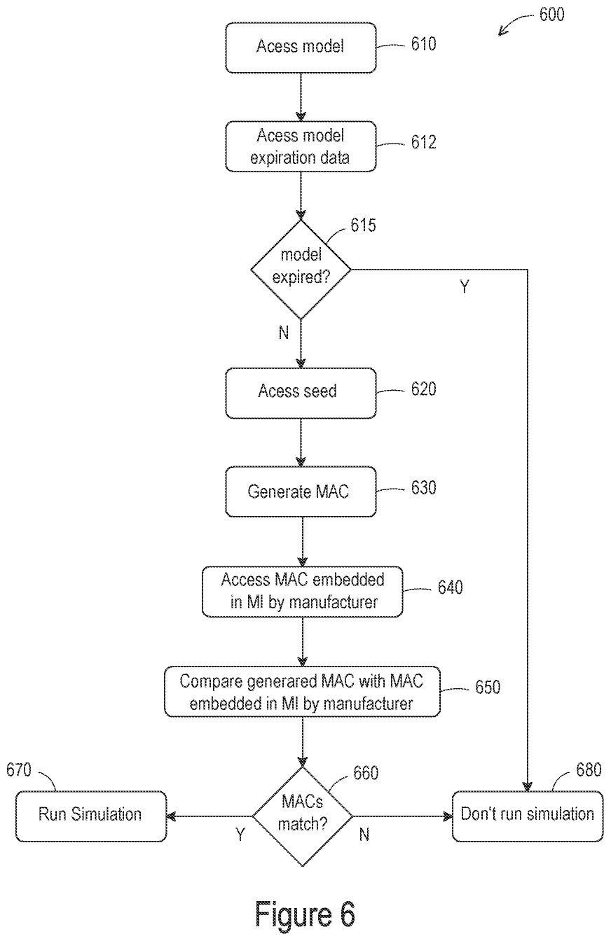

FIG. 6 is a flowchart diagram illustrating a method 600 of performing a simulation routine according to some embodiments. The method may be performed by a computer system running a simulation system comprising, for example, a simulator, such as simulator 840, discussed below with reference to FIG. 8, and having access to or running an MI, such as model interface 830, discussed below with reference to FIG. 8.

At 610, the MI accesses a semiconductor device characterization description. The semiconductor device characterization description may be valid or invalid. In some embodiments, the MI accesses the semiconductor device characterization description in response to a signal from the simulator indicating that a simulation is to be performed on a circuit using the semiconductor device characterization description, where the signal includes a specific reference to the semiconductor device characterization description.

At 612, the MI accesses an expiration date for the device mode accessed at 610.

At 615, the MI compares the expiration date accessed at 612, and compares the accessed expiration date with a comparison date, such as the current date. Based on the comparison, the MI determines whether the semiconductor device characterization description accessed at 610 has expired. For example, if the comparison date is more recent than the expiration date accessed at 612, the MI determines that the semiconductor device characterization description accessed at 610 has expired, and the method proceeds to 680, discussed below. If the comparison date is not more recent than the expiration date accessed at 612, the MI determines that the semiconductor device characterization description accessed at 610 has not expired, and the method proceeds to 620.

At 620, the MI accesses a starter code corresponding with the specific reference to the semiconductor device characterization description included in the signal from the simulator. In some embodiments, the starter code is accessible by the MI because the MI has received the starter code from a semiconductor manufacturer, for example, in a process similar to that discussed above with reference to 140 of method 10, and has stored the received starter code in a memory. Accordingly, the starter code accessed at 620 may be identical to the starter code used to generate the MAC at 130 of method 100, discussed above with reference to FIG. 1.

At 630, the MI generates a MAC based on the starter code accessed at 620 and based on the semiconductor device characterization description accessed at 610 according to a MAC generation algorithm, for example, identical to the MAC generation algorithm used at 130 of

At 640, the MI accesses a MAC corresponding with a valid model corresponding with the specific reference to the semiconductor device characterization description included in the signal from the simulator. In some embodiments, the accessed MAC is accessible by the MI because the MI has received the MAC from a semiconductor manufacturer, for example in a process similar to that discussed above with reference to 150 of method 100, and has stored the received MAC in a memory.

Accordingly, if the semiconductor device characterization description and the starter code used to generate the MAC at 630 are identical to the semiconductor device characterization description and starter code used to generate the MAC at 130 of method 100, the MAC accessed at 640 is identical to the MAC generated at 630. In contrast, if the semiconductor device characterization description or starter code used to generate the MAC at 630 are not identical to the semiconductor device characterization description or starter code used to generate the MAC at 130 of method 100, the accessed MAC is different from the MAC generated at 630.

At 650, the MAC accessed at 640 is compared with the MAC generated at 630.

If the MAC accessed at 640 is determined to be identical to the MAC generated at 630, at 660, the method continues to 670, where the simulator simulates the semiconductor circuit using the model accessed at 610, according to simulation processes and techniques known to those of skill in the art. Once the simulation completes, a result of the simulation is generated, and stored for example, as a file.

If the MAC accessed at 640 is determined to be different from the MAC generated at 630, at 660, the method continues to 680, discussed below.

In some embodiments, as a consequence of the MAC accessed at 640 being identical to the MAC generated at 630, instead of simulating the circuit at 670, the computer system repeats steps 620, 630, 640, 650, and 660, where 620 is repeated using a second seed, where 630 is repeated using a second MAC generation algorithm, where 640 is repeated using a second MAC from the semiconductor manufacturer, where 650 is repeated with the second MAC generated at the repeated instance of 630 and with the second MAC accessed at 640. In some embodiments, the MAC generation algorithm used in the first iteration of 630 is faster and/or less complicated than the MAC generation algorithm used in the second iteration of 630.

If the second accessed MAC is determined to be identical to the second MAC generated at 630, at 660, the method continues to 670, where the simulator simulates the semiconductor circuit using the model accessed at 610, according to simulation processes and techniques known to those of skill in the art. Once the simulation completes, a result of the simulation is generated, and stored for example, as a file. Because the accessed MAC and the generated MAC are compared before simulation, secure authentication of the semiconductor device characterization descriptions ensure that the proper semiconductor device characterization descriptions are used for simulating the semiconductor circuits.

If the second accessed MAC is determined to be different from the second MAC generated at 630, at 660 the method continues to 680.

At 680, the circuit is not simulated. In some embodiments, at 680, the simulator causes an error message to be displayed for a user, where the error message indicates that the semiconductor device characterization description accessed at 610 is not valid. In some embodiments, the message includes a prompt for an input indicating whether the invalid model should be used despite it being different from the model received from the semiconductor manufacturer. In some embodiments, in response to receiving an indication that the semiconductor device characterization description should be used despite it being different from the model received from the semiconductor manufacturer, the simulator simulates the circuit using the semiconductor device characterization description accessed at 610, according to simulation processes and techniques known to those of skill in the art. In some embodiments, the message includes a prompt for a new semiconductor device characterization description to be referenced. In some embodiments, if a new semiconductor device characterization description is referenced, the method 600 returns to 610 using the new semiconductor device characterization description. Because the accessed MAC and the generated MAC are compared before simulation, secure authentication of the semiconductor device characterization descriptions ensure that the improper semiconductor device characterization descriptions are not used for simulating the semiconductor circuits.

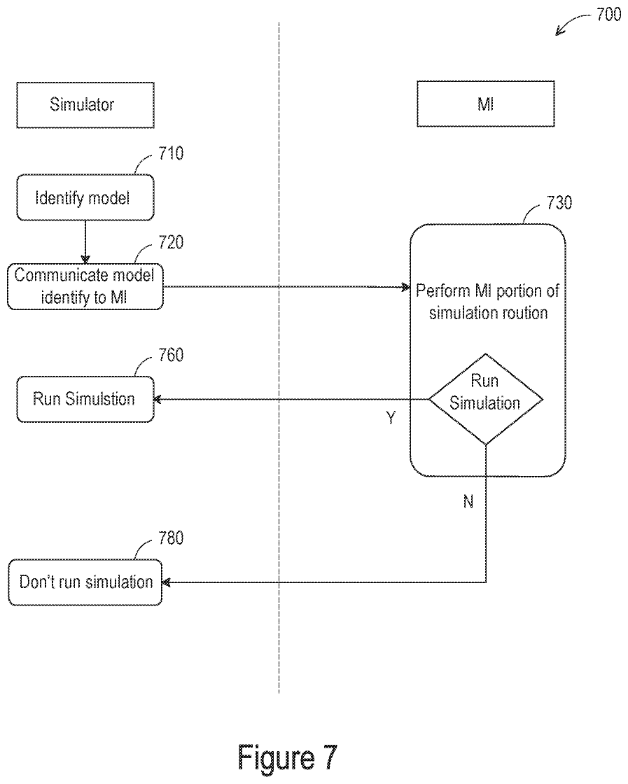

FIG. 7 is a swimming lane diagram illustrating a method 700 of simulating a circuit according to some embodiments. The method may be performed by a computer system running a simulation system comprising, for example, a simulator, such as simulator 840, discussed below with reference to FIG. 8, and having access to or running an MI, such as model interface 830, discussed below with reference to FIG. 8.

At 710, the simulator identifies a particular semiconductor device characterization description or a reference to a particular semiconductor device characterization description. The semiconductor device characterization description may be valid or invalid. In some embodiments, the simulator accesses the semiconductor device characterization description or reference to a particular semiconductor device characterization description in response to a signal indicating that a simulation is to be performed on a semiconductor circuit using the particular semiconductor device characterization description, where the signal includes a specific reference to the particular semiconductor device characterization description.

At 720, the simulator transmits the particular semiconductor device characterization description or reference to the particular semiconductor device characterization description to the MI. In some embodiments, the particular semiconductor device characterization description has an expiration date. In some embodiments, the particular semiconductor device characterization description does not have an expiration date.

At 730, the MI receives the particular semiconductor device characterization description or reference to the particular semiconductor device characterization description from the simulator. In addition, the MI performs portions of a simulation routine, such as any of the simulation routines of methods 200, 300, 400, 500, and 600. For example, at 730, the MI may perform actions similar or identical to 210, 220, 230, 240, and 250 of method 200. In some embodiments, the MI may perform actions similar or identical to 310, 320, 330, 340, and 350 of method 300. In some embodiments, the MI may perform actions similar or identical to 410, 420, 430, 440, 450, and 460 of method 400. In some embodiments, the MI may perform actions similar or identical to 510, 512, 515, 518, 520, 530, 540, 550, and 560 of method 500. In some embodiments, the MI may perform actions similar or identical to 610, 612, 615, 620, 630, 640, 650, and 660 of method 600.

The run simulation decision of the simulation routine is illustrated for convenience.

If the MI determines that the simulation is to be run, the MI transmits an allow simulation signal to the simulator, and at 760, the simulator runs the simulation. In some embodiments, at 760, the simulator may perform actions similar or identical to any of 260 of method 200, 470 of method 400, 570 of method 500, and 670 of method 600.

If the MI determines that the simulation is to not be run, the MI transmits a disallow simulation signal to the simulator, and, at 780, the simulator does not run the simulation. In some embodiments, at 780, the simulator may perform actions similar or identical to any of 360 of method 300, 480 of method 400, 580 of method 500, and 680 of method 600.

FIG. 8 is a schematic diagram illustrating a circuit simulation management system 800 which manages and authenticates semiconductor device characterization descriptions, and simulates circuits according to some embodiments.

Model generation system 810 may include a computer system which is configured to receive results of tests and to receive measured performance parameters of manufactured semiconductor devices. In some embodiments, the model generation system 810 is configured to determine values and distributions of values for each a number of parameters for each of a number of types of semiconductor devices and semiconductor structures for a mathematical representation of the device or structure behavior used for simulation. In some embodiments, model generation system 810 compiles one or more semiconductor device characterization descriptions which include parameters for the mathematical representations based on the determined values and determined distributions of values. In some embodiments, model generation system 810 is configured to communicate the one or more semiconductor device characterization descriptions to model interface 830 through communication network 820.

Communication network 820 may be any data transmission network. For example, communication network 820 may include one or more of Internet and at least one other telecommunication network.

Model interface 830 may be any model interface, and is configured to cooperatively interface with simulator 840 to simulate semiconductor circuits using semiconductor device characterization descriptions and mathematical representations of semiconductor device and structure performance, as understood by those of skill in the art. In some embodiments, model interface 830 is or includes one or more of a TSMC model interface (TMI), an open model interface (OMI), and another model interface.

Simulator 840 may be any semiconductor circuit simulator, and is configured to cooperatively interface with model interface 830 to simulate semiconductor circuits using semiconductor device characterization descriptions and mathematical representations of semiconductor device and structure performance, as understood by those of skill in the art. In some embodiments, simulator 840 includes a Spice simulation engine or other similar, as known to those of skill in the art.

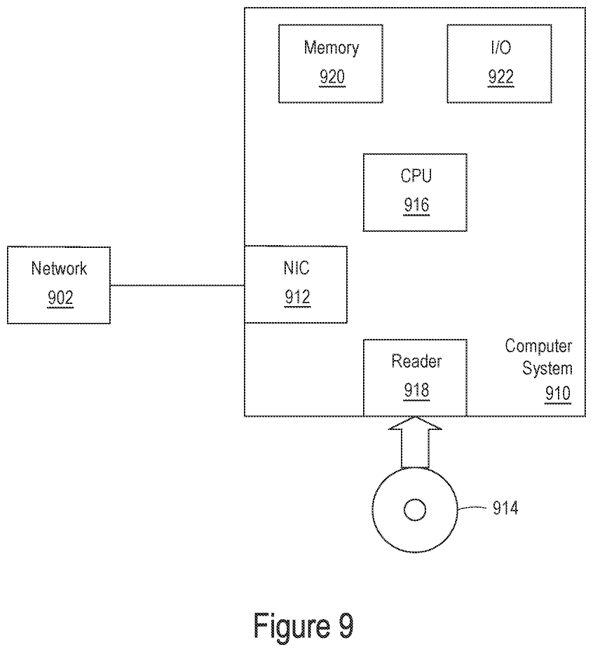

FIG. 9 shows a configuration for a computer system 910 constructed in accordance with the present disclosure for performing the operations described herein. The computer system 910 can comprise a system such as a personal computer or server computer or the like. The computer system 910 may include a network communication interface 912 that permits communications with a network 902. The network interface can comprise a network interface card (NIC). The computer system 910 can execute instructions to provide a computer system which performs various aspects and principles of the methods and features described herein for the computer of FIGS. 1-4.

The computer system 910 includes a central processor unit 916 (CPU) and a program product reader 918 for receiving a program product media and reading program instructions recorded thereon, where the instructions, when executed by the CPU of the computer system cause the computer to perform various aspects and principles of the methods and features described herein. The computer system also includes associated memory 920 and input/output facilities 922, which may include systems such as a display for output and a keyboard and/or mouse for input. The CPU 916 of the computer system 910 can receive program instructions into the program memory of the processor. The program instructions can be received directly, such as by flashing EEPROM of the processor, or can be received through the network communication interface 912, such as by download from a connected device or over a WAN or LAN network communication. If desired, the program instructions can be stored on a computer program product 914 that is read by the computer system 910 so that the program instructions can thereafter be executed. That is, the computer program product 914 is for use in a system such as the computer system 910, wherein the program product comprises a tangible, non-transitory recordable media containing a program of computer-readable instructions that are executable by the CPU 916 to perform the operations described herein. The computer program product 914 can comprise, for example, optical program media such as CD or DVD data discs, or flash memory drives, or external memory stores, or floppy magnetic disks, and the like.

One inventive aspect is a method of using a semiconductor device characterization description, the method including accessing the semiconductor device characterization description, accessing a first starter code, generating a first model authentication code (MAC) based on the semiconductor device characterization description and the first starter code, and transmitting the first starter code, the first MAC, and the semiconductor device characterization description to a model interface (MI).

In some embodiments, the semiconductor device characterization description includes one or more parameters for a semiconductor circuit simulator to simulate one or more semiconductor devices.

In some embodiments, the first MAC is generated using a MAC generation algorithm.

In some embodiments, the method also includes accessing a second starter code, generating a second MAC based on the semiconductor device characterization description and the second starter code, and transmitting the second MAC to the MI.

In some embodiments, the method also includes accessing an expiration date for the semiconductor device characterization description, and transmitting the expiration date to the MI.

In some embodiments, the MI is configured to generate a second MAC.

Another inventive aspect is a method of using a model interface. The method includes receiving a valid semiconductor device characterization description, receiving a first starter code, receiving a first model authentication code (MAC), accessing a stored semiconductor device characterization description, accessing the first starter code, accessing the first MAC, generating a second MAC based on the stored semiconductor device characterization description and the first starter code, and comparing the first MAC and the second MAC.

In some embodiments, the first MAC was generated using a particular MAC generation algorithm with the first starter code and the valid semiconductor device characterization description.

In some embodiments, the second MAC is generated using the particular MAC generation algorithm.

In some embodiments, the method also includes, in response to the first MAC and the second MAC being identical, transmitting an allow simulation signal to a simulator, the allow simulation signal configured to allow a semiconductor circuit to be simulated using the stored semiconductor device characterization description, and in response to the first MAC and the second MAC not being identical, transmitting a disallow simulation signal to the simulator, the disallow simulation signal configured to prevent the semiconductor circuit from being simulated using the stored semiconductor device characterization description.

In some embodiments, the method also includes receiving a second starter code, receiving a third MAC, accessing the second starter code, accessing the second MAC, generating a fourth MAC based on the stored semiconductor device characterization description and the second starter code, and comparing the third MAC and the fourth MAC.

In some embodiments, the third MAC was generated using a particular MAC generation algorithm with the second starter code and the valid semiconductor device characterization description, where the fourth MAC is generated using the particular MAC generation algorithm with the first starter code and the stored semiconductor device characterization description, where the method further includes in response to the third MAC and the fourth MAC being identical, transmitting an allow simulation signal to a simulator, the allow simulation signal configured to allow a semiconductor circuit to be simulated using the stored semiconductor device characterization description, and in response to the third MAC and the fourth MAC not being identical, transmitting a disallow simulation signal to the simulator, the disallow simulation signal configured to prevent the semiconductor circuit from being simulated using the stored semiconductor device characterization description.

In some embodiments, the method also includes receiving an expiration date for the valid semiconductor device characterization description, and determining whether the valid semiconductor device characterization description has expired based at least in part on the expiration date for the valid semiconductor device characterization description.

In some embodiments, the method also includes at least partly in response to the valid semiconductor device characterization description being not expired, transmitting an allow simulation signal to a simulator, the allow simulation signal configured to allow a semiconductor circuit to be simulated using the stored semiconductor device characterization description, and at least partly in response to the valid semiconductor device characterization description being expired, transmitting a disallow simulation signal to the simulator, the disallow simulation signal configured to prevent the semiconductor circuit from being simulated using the stored semiconductor device characterization description.

Another inventive aspect is a circuit simulation management system, including a model generation system, and a model interface (MI) configured to communicate with the model generation system, where the model generation system is configured to access a valid semiconductor device characterization description, access a first starter code, generate a first model authentication code (MAC) based on the valid semiconductor device characterization description and the first starter code, and transmit the first starter code, the first MAC, and the valid semiconductor device characterization description to the MI, where the MI is configured to access a stored semiconductor device characterization description, generate a second MAC based on the stored semiconductor device characterization description and the first starter code, and compare the first MAC and the second MAC.

In some embodiments, the first MAC was generated using a particular MAC generation algorithm with the first starter code and the valid semiconductor device characterization description.

In some embodiments, the second MAC is generated using the particular MAC generation algorithm.

In some embodiments, the MI is further configured to communicate with a semiconductor circuit simulator, in response to the first MAC and the second MAC being identical, transmit an allow simulation signal to a simulator, the allow simulation signal configured to allow a semiconductor circuit to be simulated using the stored semiconductor device characterization description, and in response to the first MAC and the second MAC not being identical, transmit a disallow simulation signal to the simulator, the disallow simulation signal configured to prevent the semiconductor circuit from being simulated using the stored semiconductor device characterization description.

In some embodiments, the MI is further configured to receive an expiration date for the valid semiconductor device characterization description, and determine whether the valid semiconductor device characterization description has expired based at least in part on the expiration date for the valid semiconductor device characterization description.

In some embodiments, the MI is further configured to at least partly in response to the valid semiconductor device characterization description being not expired, transmit an allow simulation signal to a simulator, the allow simulation signal configured to allow a semiconductor circuit to be simulated using the stored semiconductor device characterization description, and at least partly in response to the valid semiconductor device characterization description being expired, transmit a disallow simulation signal to the simulator, the disallow simulation signal configured to prevent the semiconductor circuit from being simulated using the stored semiconductor device characterization description.

In the descriptions above and in the claims, phrases such as “at least one of” or “one or more of” may occur followed by a conjunctive list of elements or features. The term “and/or” may also occur in a list of two or more elements or features. Unless otherwise implicitly or explicitly contradicted by the context in which it used, such a phrase is intended to mean any of the listed elements or features individually or any of the recited elements or features in combination with any of the other recited elements or features. For example, the phrases “at least one of A and B;” “one or more of A and B;” and “A and/or B” are each intended to mean “A alone, B alone, or A and B together.” A similar interpretation is also intended for lists including three or more items. For example, the phrases “at least one of A, B, and C;” “one or more of A, B, and C;” and “A, B, and/or C” are each intended to mean “A alone, B alone, C alone, A and B together, A and C together, B and C together, or A and B and C together.” Use of the term “based on,” above and in the claims is intended to mean, “based at least in part on,” such that an unrecited feature or element is also permissible.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method of using a semiconductor device characterization description, the method comprising:
accessing the semiconductor device characterization description;
accessing a first starter code;
generating a first model authentication code (MAC) based on the semiconductor device characterization description and the first starter code; and
transmitting the first starter code, the first MAC, and the semiconductor device characterization description to a model interface (MI).

2. The method of claim 1, wherein the semiconductor device characterization description comprises one or more parameters for a semiconductor circuit simulator to simulate one or more semiconductor devices.

3. The method of claim 1, wherein the first MAC is generated using a MAC generation algorithm.

4. The method of claim 1, further comprising:
accessing a second starter code;
generating a second MAC based on the semiconductor device characterization description and the second starter code; and
transmitting the second MAC to the MI.

5. The method of claim 1, further comprising:
accessing an expiration date for the semiconductor device characterization description; and
transmitting the expiration date to the MI.

6. The method of claim 1, wherein the MI is configured to generate a second MAC.

7. A method of using a model interface, the method comprising:
receiving a valid semiconductor device characterization description;
receiving a first starter code;
receiving a first model authentication code (MAC);
accessing a stored semiconductor device characterization description;
accessing the first starter code;
accessing the first MAC;
generating a second MAC based on the stored semiconductor device characterization description and the first starter code; and
comparing the first MAC and the second MAC.

8. The method of claim 7, wherein the first MAC was generated using a particular MAC generation algorithm with the first starter code and the valid semiconductor device characterization description.

9. The method of claim 8, wherein the second MAC is generated using the particular MAC generation algorithm.

10. The method of claim 7, further comprising:
in response to the first MAC and the second MAC being identical, transmitting an allow simulation signal to a simulator, the allow simulation signal configured to allow a semiconductor circuit to be simulated using the stored semiconductor device characterization description; and
in response to the first MAC and the second MAC not being identical, transmitting a disallow simulation signal to the simulator, the disallow simulation signal configured to prevent the semiconductor circuit from being simulated using the stored semiconductor device characterization description.

11. The method of claim 7, further comprising:
receiving a second starter code;
receiving a third MAC;
accessing the second starter code;
accessing the second MAC;
generating a fourth MAC based on the stored semiconductor device characterization description and the second starter code; and
comparing the third MAC and the fourth MAC.

12. The method of claim 11, wherein the third MAC was generated using a particular MAC generation algorithm with the second starter code and the valid semiconductor device characterization description, wherein the fourth MAC is generated using the particular MAC generation algorithm with the first starter code and the stored semiconductor device characterization description, wherein the method further comprises:
in response to the third MAC and the fourth MAC being identical, transmitting an allow simulation signal to a simulator, the allow simulation signal configured to allow a semiconductor circuit to be simulated using the stored semiconductor device characterization description; and
in response to the third MAC and the fourth MAC not being identical, transmitting a disallow simulation signal to the simulator, the disallow simulation signal configured to prevent the semiconductor circuit from being simulated using the stored semiconductor device characterization description.

13. The method of claim 7, further comprising:
receiving an expiration date for the valid semiconductor device characterization description; and
determining whether the valid semiconductor device characterization description has expired based at least in part on the expiration date for the valid semiconductor device characterization description.

14. The method of claim 7, further comprising:
at least partly in response to the valid semiconductor device characterization description being not expired, transmitting an allow simulation signal to a simulator, the allow simulation signal configured to allow a semiconductor circuit to be simulated using the stored semiconductor device characterization description; and
at least partly in response to the valid semiconductor device characterization description being expired, transmitting a disallow simulation signal to the simulator, the disallow simulation signal configured to prevent the semiconductor circuit from being simulated using the stored semiconductor device characterization description.

15. A circuit simulation management system, comprising:
a model generation system; and
a model interface (MI) configured to communicate with the model generation system,
wherein the model generation system is configured to:
access a valid semiconductor device characterization description;
access a first starter code;
generate a first model authentication code (MAC) based on the valid semiconductor device characterization description and the first starter code; and
transmit the first starter code, the first MAC, and the valid semiconductor device characterization description to the MI,
wherein the MI is configured to:
access a stored semiconductor device characterization description;
generate a second MAC based on the stored semiconductor device characterization description and the first starter code; and
compare the first MAC and the second MAC.

16. The circuit simulation management system of claim 15, wherein the first MAC was generated using a particular MAC generation algorithm with the first starter code and the valid semiconductor device characterization description.

17. The circuit simulation management system of claim 16, wherein the second MAC is generated using the particular MAC generation algorithm.

18. The circuit simulation management system of claim 15, wherein the MI is further configured to:
communicate with a semiconductor circuit simulator;
in response to the first MAC and the second MAC being identical, transmit an allow simulation signal to a simulator, the allow simulation signal configured to allow a semiconductor circuit to be simulated using the stored semiconductor device characterization description; and
in response to the first MAC and the second MAC not being identical, transmit a disallow simulation signal to the simulator, the disallow simulation signal configured to prevent the semiconductor circuit from being simulated using the stored semiconductor device characterization description.

19. The circuit simulation management system of claim 15, wherein the MI is further configured to:
receive an expiration date for the valid semiconductor device characterization description; and
determine whether the valid semiconductor device characterization description has expired based at least in part on the expiration date for the valid semiconductor device characterization description.

20. The circuit simulation management system of claim 19, wherein the MI is further configured to:
at least partly in response to the valid semiconductor device characterization description being not expired, transmit an allow simulation signal to a simulator, the allow simulation signal configured to allow a semiconductor circuit to be simulated using the stored semiconductor device characterization description; and
at least partly in response to the valid semiconductor device characterization description being expired, transmit a disallow simulation signal to the simulator, the disallow simulation signal configured to prevent the semiconductor circuit from being simulated using the stored semiconductor device characterization description.
